(19) United States
(12) Patent Application Publication
(10) Pub. No.: US 2019/0372294 A1
(43) Pub. Date: Dec. 5, 2019

(54) APPARATUS AND METHOD FOR WIRE PREPARATION

(71) Applicant: The Charles Stark Draper Laboratory, Inc., Cambridge, MA (US)

(72) Inventors: Mitchell W. Meinhold, Cambridge, MA (US); Jeffery Delisio, Cambridge, MA (US); Ernest Soonho Kim, Cambridge, MA (US); Caprice Gray Haley, Cambridge, MA (US)

(21) Appl. No.: 16/430,996

(22) Filed: Jun. 4, 2019

Related U.S. Application Data
(60) Provisional application No. 62/680,124, filed on Jun. 4, 2018.
(60) Provisional application No. 62/856,313, filed on Jun. 3, 2019.

(51) Int. Cl. H01R 43/28; H01L 23/00

(52) U.S. Cl. CPC H01R 43/28; H01L 24/78; H01L 2224/78253; H01L 2224/78252; H01L 2224/78702; H01L 2224/78502; H01L 2224/78282; H01L 2224/78268; H01L 2224/7801; H01L 2224/78611; H01L 2224/78756

(57) ABSTRACT

A wire bonding tool for bonding a micro-coaxial wire to a bonding surface includes an electrical-energy application mechanism configured to apply electrical-energy to remove a portion of an electrically conductive shield layer of the micro-coaxial wire to expose a portion of an insulating layer of the micro-coaxial wire, a thermal-energy application mechanism configured to apply thermal-energy to the micro-coaxial wire to remove the exposed portion of the insulating layer of the micro-coaxial wire to expose a portion of a core wire of the micro-coaxial wire, and a bonding head configured to bond the exposed portion of the core wire of the micro-coaxial wire to the bonding surface.

### CROSS-REFERENCE TO RELATED APPLICATIONS

This application claims the benefit of U.S. Provisional Application No. 62/680,124 filed Jun. 4, 2018 and U.S. Provisional Application No. 62/856,313 filed Jun. 3, 2019. The contents of both provisional applications are incorporated herein by reference.

### BACKGROUND

This invention relates to preparation and bonding of micro-coaxial wires.

Conventional wire bonding tools are used to make electrical interconnections between integrated circuits or other semiconductor devices and their packaging during semiconductor device fabrication. In some examples, wire bonding tools are used to connect integrated circuits to other electronics or to connect one printed circuit board to another.

### SUMMARY

Conventional wire bonders used for creating interconnects in microelectronic systems are unable to bond or strip micro-coaxial wires. Aspects described herein are configured to strip and bond micro-coaxial wires that look like traditional bond wires on the outside but contain a dielectric separating the core (the primary interconnect for energy propagation) from a shield (responsible for ground returns and preventing electromagnetic interactions with adjacent wires).

To make an electrical contact with the core of a micro-coaxial wire, the shield and the dielectric of that wire must be stripped prior to bonding. Furthermore, in some examples, because the micro-coaxial wires include two conductors instead of one, two independent electrical contacts must be made. Some aspects described herein are configured to make two independent electrical contacts per bond site rather than the single electrical contact that conventional wire bonders are configured to make per bond site.

In a general aspect, a wire bonding tool for bonding a micro-coaxial wire to a bonding surface includes an electrical-energy application mechanism configured to apply electrical-energy to remove a portion of an electrically conductive shield layer of the micro-coaxial wire to expose a portion of an insulating layer of the micro-coaxial wire, a thermal-energy application mechanism configured to apply thermal-energy to the micro-coaxial wire to remove the exposed portion of the insulating layer of the micro-coaxial wire to expose a portion of a core wire of the micro-coaxial wire, and a bonding head configured to bond the exposed portion of the core wire of the micro-coaxial wire to the bonding surface.

Aspects may have one or more of the following features.

The bonding head may be further configured to bond a portion of the shield layer proximal to the exposed portion of the core wire to a second bonding surface. The wire bonding tool may include a positioning mechanism located proximal to the bonding head and configured to position the exposed portion of the core wire for bonding to the bonding surface. The electrical-energy application mechanism may be disposed at a first distance from the bonding head along a path of travel of the micro-coaxial wire and the thermal-energy application mechanism may be disposed at a second distance from the bonding head along the path of travel of the micro-coaxial wire. The first distance and the second distance may be equal.

The thermal-energy application mechanism may include one or more resistively heated elements. The thermal-energy application mechanism may include one or more guide elements for maintaining the micro-coaxial wire in a position on or near the one or more resistively heated elements. The one or more guide elements may include a number of ceramic members positioned adjacent to the one or more resistively heated elements. The one or more resistively heated elements may include a first resistively heated wire configured to have a first current flow in a first direction therethrough and a second resistively heated wire configured to have a second current flow in a second direction, opposite to the first direction, therethrough, whereby a magnetic field is induced causing the first resistively heated wire and the second resistively heated wire to approach each other.

The electrical-energy application mechanism may be configured to apply an electric spark to the shield layer of the micro-coaxial wire. The electric spark may include a high-voltage plasma discharge. The wire bonding tool may include a debris removal mechanism for removal of debris from one or both of the exposed portion of the insulating layer of the micro-coaxial wire and the exposed portion of the core wire of the micro-coaxial wire.

The wire bonding tool may include a feed mechanism for feeding the micro-coaxial wire through the wire bonding tool along a wire travel axis. The feed mechanism may include a servo motor configured to rotate a wire feed roller engaged with the micro-coaxial wire. The wire feed mechanism may be rotatable about a hinge into a first position where the wire feed roller is engaged with the micro-coaxial wire and into a second position where the wire feed roller is disengaged from the micro-coaxial wire. The wire feed mechanism may be biased toward the first position by a spring. The thermal-energy application mechanism may include a manifold for directing a forced gas onto the micro-coaxial wire. The forced gas may include nitrogen gas. The forced gas may include a cooling gas.

One or both of the thermal-energy application mechanism and the electrical-energy application mechanism may include adjustment elements for adjusting a position of portions of the mechanisms and the micro-coaxial wire.

In another general aspect, a method for preparing a micro-coaxial wire for bonding to a bonding surface includes applying electrical-energy to a micro-coaxial wire to remove a portion of an electrically conductive shield layer of the micro-coaxial wire to expose a portion of an insulating layer of the micro-coaxial wire and applying thermal-energy to the micro-coaxial wire to remove the exposed portion of the insulating layer of the micro-coaxial wire to expose a portion of a core wire of the micro-coaxial wire.

In some aspects, the electrical-energy and the thermal energy are applied simultaneously.

Aspects may have one or more of the following advantages.

Among other advantages, aspects described herein include a wire bonding tool that can not only strip wires before bonding, but also strip very small, micro-coaxial wires before bonding.

Aspects are advantageously able to bond both the conductive core of a micro-coaxial wire and the conductive shield of the micro-coaxial wire.

Other features and advantages of the invention are apparent from the following description, and from the claims.

### DESCRIPTION OF DRAWINGS

FIG. 1 is a wire bonding tool.

FIG. 2 is a wire bonding tool in a disengaged configuration.

FIG. 3 is a bottom view of the wire bonding tool of FIG. 2.

FIG. 4 is a micro-coaxial wire prior to an electric flame-off stripping procedure.

FIG. 5 is the micro-coaxial wire of FIG. 4 after the electric flame-off stripping procedure and prior to a thermal stripping procedure.

FIG. 6 is the micro-coaxial wire of FIG. 5 after the thermal stripping procedure.

FIG. 7 is a wire stripping mechanism.

FIG. 8 is a thermal stripping mechanism.

FIG. 9 is a wire feed mechanism.

FIG. 10 is a schematic diagram of a system including the wire bonding tool.

FIG. 11 is a wire bonding method.

### DESCRIPTION

### 1 Wire Bonding Tool

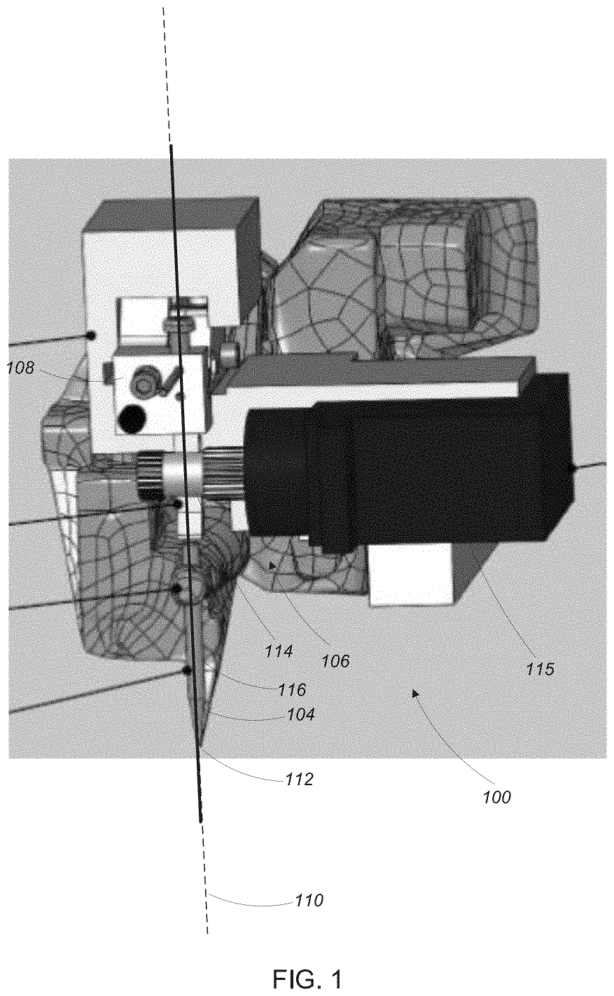

Referring to FIGS. 1-3, a wire bonding tool 100 is configured to strip a micro-coaxial wire 102 and to bond the stripped wire to a bonding surface (not shown). The wire bonding tool 100 includes a wire stripping mechanism 108, a wire feeding mechanism 106, and a bonding head 104.

In general, the micro-coaxial wire 102 extends through the wire bonding tool 100 along a wire travel axis 110. The wire travel axis 110 extends through an opening (not shown) in the wire stripping mechanism 108, past a wire feed roller 114 of the wire feeding mechanism 106, through a capillary 116 attached to the bonding head 104 and out of an opening 112 of the bonding head 104.

In operation, the wire feed roller 114 of the wire feeding mechanism 106 engages the micro-coaxial wire 102 and rotates to draw the micro-coaxial wire 102 along the wire travel axis 110. When the micro-coaxial wire 102 is drawn a predetermined distance along the wire travel axis 110, the wire feed roller 114 of the feeding mechanism 106 stops rotating and a portion of the micro-coaxial wire 102 that is located in the wire stripping mechanism 108 is stripped, as is described in greater detail below.

After the portion of the micro-coaxial wire 102 is stripped, the wire feed roller 114 of the wire feeding mechanism 106 again rotates to move the stripped portion of the micro-coaxial wire 102 along the wire travel axis 110 and through the capillary 116 of the bonding head 104 until at least part of the stripped portion of the micro-coaxial wire 102 emerges from the opening 112 of the bonding head 104. The stripped portion of the micro-coaxial wire 102 is then bonded to the bonding surface by the bonding head 104.

### 1.1 Wire Stripping Mechanism

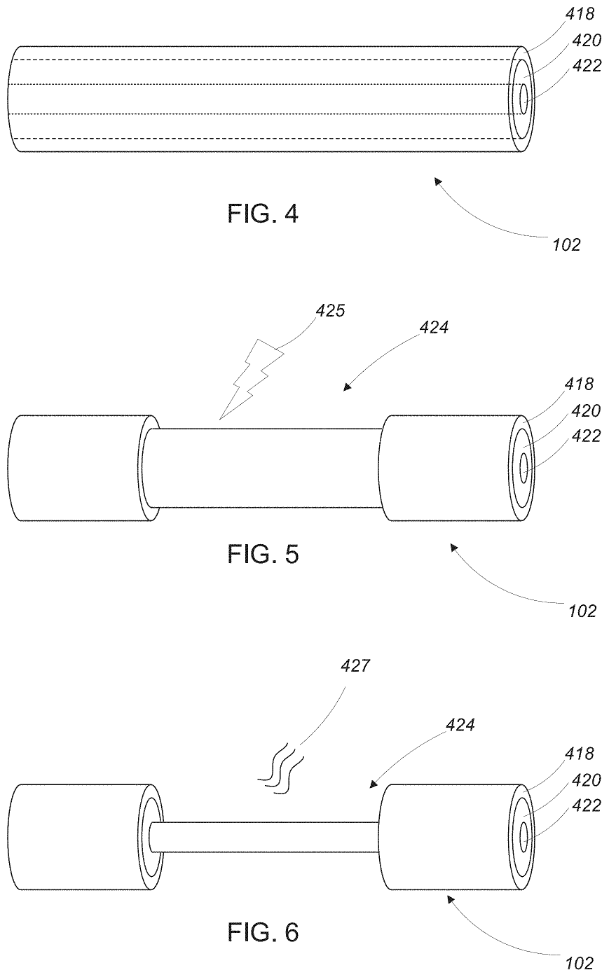

Very generally, the wire stripping mechanism 108 is configured to strip micro-coaxial wires such as the micro-coaxial wires described in PCT/US17/32136, filed May 11, 2017, titled “Wiring System,”, which is incorporated herein by reference. Referring to FIGS. 4-6, the micro-coaxial wires 102 have a very small diameter (e.g., 200 μm or less) and include a conductive core wire 422 (e.g., a Cu wire) with a dielectric insulating layer 420 (e.g., a layer of Parylene C) disposed thereon. A conductive shield layer 418 (e.g., a layer of Au) is disposed on the dielectric insulating layer 420.

There are two main configurations of the micro-coaxial wires 102: a first configuration for carrying power (e.g., signals for routing power to circuit components) and a second configuration for carrying signals (e.g., radio frequency signals).

Wires of the first configuration have a center conductor with a diameter in a range of 10 μm to 35 μm, depending on the required current capacity and conductivity of the core metal; a dielectric insulating layer 420 with a thickness in a range of 0.5 μm to 7 μm, depending on the dielectric constant and length of the power transmission line; and a conductive shield layer 418 with a thickness in a range of 2 μm to 10 μm; depending on the ratio of the core conductance to shield conductance. As a result, a typical target characteristic impedance of the wires of the first configuration is in a range of 1Ω to 10Ω, depending on the power distribution network circuit requirements.

Wires of the second configuration have a center conductor with a diameter in a range of 10 μm to 25 μm, depending on signal transmission distance; a dielectric insulating layer 420 with a thickness in a range of 10 μm to 140 μm, depending on the characteristic impedance requirements at the end contact points of the wires, the dielectric constant of the insulating material and the core diameter; and a conductive shield layer 418 with a thickness in a range of 2 μm to 10 μm, depending on the ratio of the core to shield conductance and the frequency of the signal being transmitted. As a result, a characteristic impedance of the wires of the second configuration is in a range of 40Ω to 75Ω, which is suitable for most applications.

For both configurations of the micro-coaxial wires, traditional wire stripping techniques cannot be used to strip the micro-coaxial wires due to the very small diameters of the wires. Instead, a two-step wire stripping procedure is applied to a portion of a micro-coaxial wire to expose a portion of the conductive core of the micro-coaxial wire.

Referring to FIG. 4, prior to performing the two-step wire stripping procedure, the conductive shield layer 418 and a dielectric insulating layer 420 of a micro-coaxial wire 102 are intact, covering the conductive core wire 422 of the micro-coaxial wire 102.

Referring to FIG. 5, a first step of the two-step wire stripping procedure is performed, removing the conductive shield layer 418 from the dielectric insulating layer 420 over a portion 424 of the micro-coaxial wire 102. Very generally, the first step is performed by exposing the conductive shield layer 418 to a high voltage plasma discharge 425 (sometimes referred to as a ‘spark’) generated by an electric flame-off mechanism (not shown and described in greater detail below). After the first step of the two-step wire stripping procedure, the dielectric insulating layer 420 is exposed in the portion 424 of the micro-coaxial wire 102.

Referring to FIG. 6, a second step of the two-step wire stripping procedure is performed, removing the dielectric insulating layer 420 from the conductive core wire 422 over the portion 424 of the micro-coaxial wire 102. Very generally, the second step is performed by exposing the dielectric insulating layer 420 to thermal energy 427 generated by a thermal stripping mechanism (not shown and described in greater detail below). After the second step of the two-step wire stripping procedure, the conductive core is exposed in the portion 424 of the micro-coaxial wire 102.

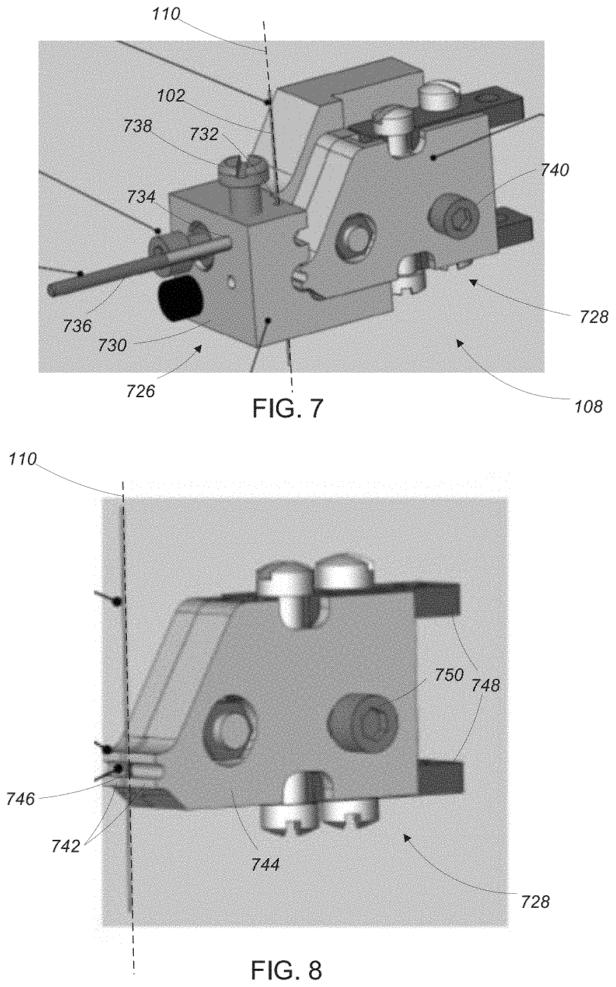

Referring to FIG. 7, the wire stripping mechanism 108 that performs the two-step wire stripping procedure described above includes an electric flame-off mechanism 726 and a thermal stripping mechanism 728.

### 1.1.1 Electric Flame-Off Mechanism

As is mentioned above, the electric flame-off mechanism 726 exposes the conductive shield layer 418 of a portion of a micro-coaxial wire 102 to a high voltage plasma discharge to remove the conductive shield layer 418 from that portion of the wire (i.e., the electric flame-off mechanism 726 causes the transition from the wire configuration of FIG. 4 to the wire configuration of FIG. 5).

The electric flame-off mechanism 726 includes a body 730 with a channel 732 and an electric flame-off port 734 extending therethrough. The channel 732 is coaxial with the wire travel axis 110 such that the micro-coaxial wire 102 extends along the wire travel axis 110 through the channel 732. The electric flame-off port 734 extends substantially perpendicular to the channel 732 and is configured to receive an electric flame-off actuator 736 (e.g., a spark generator). When disposed in the electric flame-off port 734, the electric flame-off actuator 736 is positioned adjacent to the channel 732 (and any micro-coaxial wire disposed therein). In some examples, the electric flame-off mechanism 726 includes a vertical adjustment screw 738 for adjusting a vertical position of the electric flame-off actuator 736 along the micro-coaxial wire 102. The electric flame-off mechanism 726 also includes, in some examples, a horizontal adjustment screw 740 for adjusting a distance between the electric flame-off actuator 736 and the micro-coaxial wire 102.

### 1.1.1.1 Miscellaneous Electric Flame-Off Mechanism Features

In some examples, low impedance micro-coaxial wires (i.e., those with impedance less than 10Ω) for power distribution are prone to cleaving of the conductive core wire during the electric flame-off stripping process. To identify ideal operation of the electric flame-off shield stripping conditions for low impedance micro-coaxial wire settings on the electric flame-off actuator 736 are varied to create a parameter map that identifies optimal electric-flame-off settings. To do so, power and time on the electric flame-off actuator is varied and the result of stripping the coaxial wire is recorded (e.g., whether or not the conductive core wire cleaved). Certain parameters affect whether or not the conductive core wire cleaved, the parameters including conductive shield thickness and a distance between the center of the coaxial wire and the electric flame-off actuator 736. Settings that result in non-breakage of the conductive core wire were determined for micro-coaxial wires with conductive shields with thicknesses in the range of 0.36 μm to 10.11 μm, even while varying the distance between the electric flame-off actuator 736 and the center point on the wire between 650 μm to 1250 μm.

In some examples, micro-coaxial wires with gold (Au) conductive shields having thicknesses in the range of 4-8 μm are best suited for removal of the conductive shield without cleaving the conductive core wire. For a micro-coaxial wire with ˜4.65 μm shield thickness, the optimal settings were determined to be a power setting between 4-6 (out of a 1-10 dial setting on a commercial wire bonder) and time setting between 3 ms-5 ms. The optimal setting for a micro-coaxial wire with ˜6.8 um shield thickness was determined to be a power setting between 7-8 (out of a 1-10 dial setting on a commercial wire bonder) and time setting between 3 ms-6 ms.

### 1.1.2 Thermal Stripping Mechanism

Referring to FIG. 8, the thermal stripping mechanism 728 includes a body 744 with two ceramic guide rails 742. An electric heating element 746 is disposed in a space between the two ceramic guide rails 742 and is powered by way of two electrical connectors 748. The thermal stripping mechanism 728 is positioned such that the wire travel axis 110 extends through the space between the two guide rails 742 and is adjacent to the heating element 746 such that the micro-coaxial wire 102 is disposed between the guide rails 742 and near the heating element 746. The ceramic guide rails 742 ensure that the micro-coaxial wire 102 remains centered and adjacent to (or in contact with) the heating element 746 as it is drawn through the thermal stripping mechanism 728.

### 1.1.2.1 Miscellaneous Thermal Stripping Mechanism Features

In some examples, the electric heating element 746 includes one or more electrically resistive wires such as Nichrom, Kanthal, or W wire. For thicker dielectrics, two wires are used on either side of the dielectric. Current is run in opposite directions through the adjacent thermal wires and the induced magnetic field draws the thermal wires towards each other, acting like a clamp during dielectric removal.

A number of variables can cause the micro-coaxial wire to stick to the heating element 746, including but not limited to position of the heating element 746 relative to the wire, thickness of the insulating dielectric layer, power and time parameters, and behavior of the melting polymer during the heating process. In some examples, one or more set screws 750 allow for adjustment of the position of the heating element 746 relative to the micro-coaxial wire 102 to offset the heating element 746 from the wire in controllable increments.

In some examples, other measures are taken to ensure that the thermal stripping mechanism does not overheat to a point that incoming sections of micro-coaxial wire to inadvertently melt and/or stick to certain elements of the heating element 746 during rapid sequential operation. One such measure is to reduce the volume and/or effective length of the heating element 746 as much as possible. One way of doing so is to run copper leads in proximity to where the heating element 746 heats the wire. In doing so, the power input to the heating element 746 is reduced because the length of the heating element 746 is reduced. In yet other examples, excess heat is mitigated by adding heat sinks and/or air-cooling features to the thermal stripping mechanism 728.

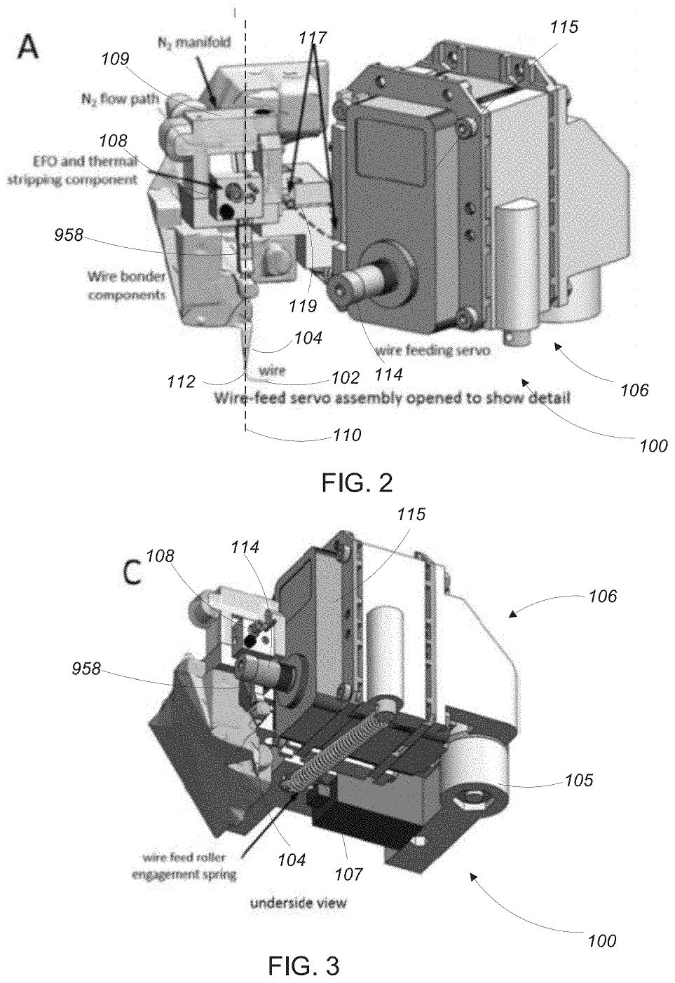

In some examples, when using Parylene C dielectric (or other oxygen sensitive dielectrics), the thermal stripping process can cause significant charring. One way to mitigate this charring is to implement a flow of nitrogen gas over the wire during the thermal stripping process. In some examples, the thermal stripping mechanism includes a nitrogen manifold (see FIG. 2, element 109) to mitigate charring during the thermal stripping process.

In some examples, a certain amount of insulating dielectric material remains on the central conductive core after the thermal stripping process (possibly due to the fact that hydrophilic copper oxide results in lack of ability of molten polymer to fully de-wet the surface of the conductive core during thermal stripping). This issue is mitigated in some examples by surface metal finishing a copper conductive core with gold (which has better Parylene de-wetting properties than copper). Other ways of mitigating this issue include surface chemical modification (e.g., HDMS) or a change in the polymer chemistry of the insulating dielectric layer.

In other examples, the thermal stripping mechanism 728 includes an atmospheric plasma cleaning apparatus (not shown) to remove any remaining insulating dielectric material on the central conductive core.

### 1.2 Wire Feeding Mechanism

Referring again to FIGS. 2-3, the wire feeding mechanism 106 includes a wire feeding servo 115 that drives the wire feed roller 114. In operation, the wire feed roller 114 presses the micro-coaxial wire 102 against a wire feed block 958 such that a frictional force exists between the micro-coaxial wire 102, the wire feed roller 114, and the wire feed block. When the wire feeding servo 115 causes the wire feed roller 114 to rotate, the frictional force causes the micro-coaxial wire 102 to move substantially along the wire travel axis 110.

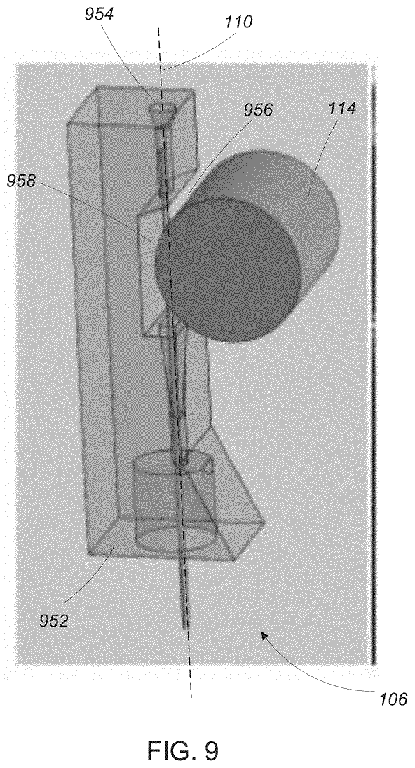

Referring to FIG. 9, in some examples, the wire feeding mechanism 106 has a body 952 with a channel 954 extending therethrough along the wire travel axis 110. The body 952 includes a cut-away notch 956 where the micro-coaxial wire 102 is outside of the channel 954 and the wire feed block 958 is exposed (where the micro-coaxial wire 102 is disposed between the wire feed block 958 and the wire feed roller 114. When engaged, the wire feed roller 114 extends into the cut-away notch 952 to contact and press the micro-coaxial wire 102 against the wire feed block 958.

Referring again to FIGS. 2-3, in some examples, the wire feeding mechanism 106 engages/disengages the micro-coaxial wire 102 by rotating about a hinge 105. For example, when loading wire or making adjustments to the thermal stripping mechanism 728, the wire feeding mechanism 106 is disengaged from the micro-coaxial wire 102 by rotating the wire feeding mechanism 106 away from the micro-coaxial wire using the hinge 105. After loading the micro-coaxial wire 102, the wire feeding mechanism 106 is rotated back into place, where it re-engages the micro-coaxial wire 102.

### 1.2.1.1 Miscellaneous Wire Feeding Mechanism Features

In some examples, the force applied by the wire feed roller 114 on the micro-coaxial wire 102 and wire feed block 958 is supplemented to prevent the wire from binding during the thermal stripping procedure. In one configuration, the supplemental force is generated by an electromagnet that draws the wire feed roller 114 (rotating on the hinge 105) toward the wire feed block 958. In other examples, and as is shown in FIG. 3, a spring 107 connected between the wire feeding mechanism 106 and a body 119 of the wire bonding tool 100 is used to provide the supplemental force, preventing unnecessary heating the system, obviating the need for an electromagnetic coil.

In some examples, a pin and groove lock 117 is included to fix the vertical position of the wire feeding mechanism 106 relative to a vertical position of the body 119 of the wire bonding tool 100.

In some examples, the wire feeding mechanism 106 includes a linear encoder to track movement of the micro-coaxial wire 102 along the wire travel axis 110. Furthermore, in some examples, the wire feeding servo 115 includes a rotary encoder that utilizes operational motion feedback to improve wire-feed precision. For example, a controller can monitor rotation angle of the wire feed roller 114 during wire feed operations. Whereas some control systems use time and speed to perform motion, a control system using a rotary encoder takes an angle of rotation as a raw input (an optionally a rotational velocity). In some examples, the control system includes an automatic slowdown procedure to direct the wire feeding servo 115 to shift to slow speed once its position comes to within about 60 degrees of its target angular position to prevent rotation overshoot.

In some examples, the wire feed roller 114 is made from a soft (e.g., rubberized or foam) material to reduce the potential for damaging the micro-coaxial wire 102.

### 1.3 Bonding Head

The bonding head 104 shown in FIGS. 1-3 includes a channel (not shown) extending along the wire travel axis 110 and configured to receive the micro-coaxial wire 102 after it has been stripped by the wire stripping mechanism 108. In operation, the micro-coaxial wire 102 (including the exposed portion of the conductive core wire 422) is fed through the capillary 116, into channel in the bonding head 104, and emerges from the opening 112 at the end of the bonding head 104.

The exposed portion 424 of the conductive core wire 422 wire exits the channel via the opening 112 and is positioned by moving the wire bonding tool 100. Once in position, the exposed portion of the conductive core wire 422 is bonded to the bonding surface using the bonding head 104. In some examples, the bonding head 104 also bonds the shield layer of the micro-coaxial wire to another part (e.g., a ground contact) of the bonding surface (e.g., using an ultrasonic bonding technique).

### 1.3.1 Miscellaneous Bonding Head Features

As is described above, the channel in the bonding head 104 is attached to an elongate ceramic “capillary” tube though which the micro-coaxial wire 102 travels. Some standard capillaries have exit holes that are sized to accommodate bond wire with diameters in the range of 0.7-1.5 mil. But due to the stripping procedure described herein, certain parts of the stripped micro-coaxial wire 102 may exceed the inner diameters of the exit holes of those standard capillaries. In some examples, capillaries with oversized exit (e.g., 2.7 and 3.3 mil) are fabricated in order to be compatible with maximum feature diameters of 2 to 2.5 mil. Larger capillary exit holes may be considered. In other examples, existing capillaries are modified. This is possible because there is a taper in the exit hole of standard 1.2 mil (30 um) sized capillaries. Using a diamond-based abrasive, a standard capillary tip is modified yielding a capillary with an opening sufficient to allow passage of stripped micro-coaxial wire having a melt bead having a diameter of up to about 2 mil. The working bond surface of the capillary is comparable to existing PEG bond tools (50-100 μm diameter).

In some examples, the capillary is mechanically isolated from the wire feeding mechanism 106 to avoid damping the vibration action of the capillary during a bonding operation.

### 2 Schematic Diagram

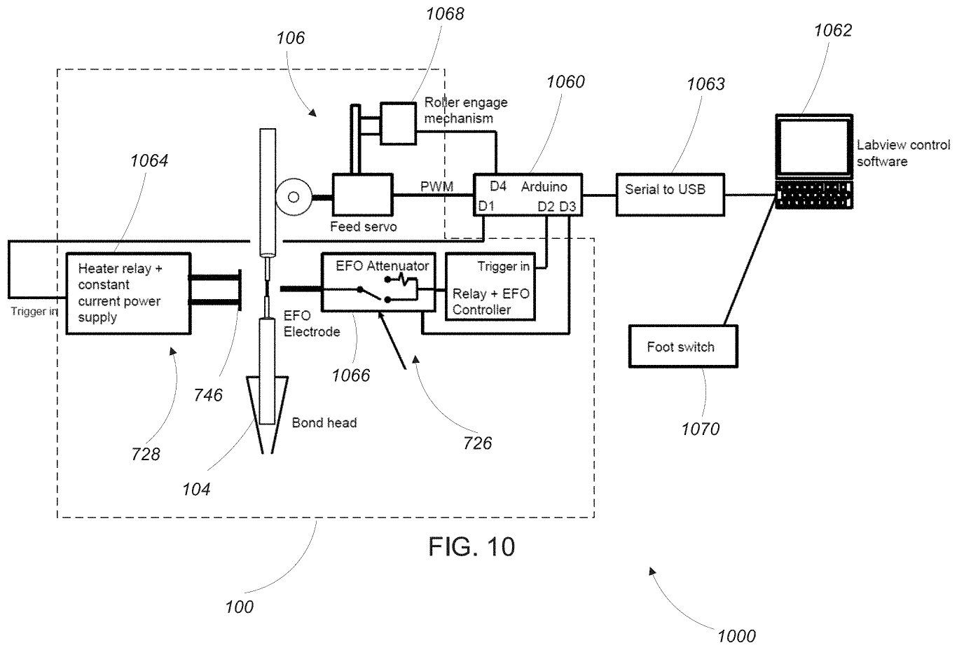

Referring to FIG. 10, a schematic diagram 1000 shows one example of a system for controlling the various components the wire bonding tool 100. The system includes the wire bonding tool 100 including the wire stripping mechanism 108, the wire feeding mechanism 106, and the wire bonding head 104. The system also includes a controller 1060 connected to a computer 1062 (e.g., via serial to USB device 1063). The controller 1060 includes a number of control outputs including a first control output “D1” connected to a power supply 1064 for the thermal stripping mechanism 728. The first control output “D1” provides a trigger signal to toggle the thermal stripping mechanism 728 between an ‘ON’ and ‘OFF’ state (or possibly through any number of states between fully on and fully off).

A second control output “D2” is connected to circuitry for controlling the electric flame-off mechanism 726. The second control output “D2” provides a trigger signal to cause the electric flame-off mechanism 726 to generate a high voltage plasma discharge to strip the conductive shield layer 418 from the micro-coaxial wire 102. In some examples, the circuitry for controlling the electric flame-off mechanism 726 includes a switchable attenuator 1066. A third control output “D3” is connected to the switchable attenuator 1066 and toggles the switchable attenuator 1066 between an “attenuated” state and a “non-attenuated” state. In general, the in the attenuated state a power output from an electric flame-off controller (not shown) is reduced (e.g., when stripping thinner shields on smaller wires) and in the non-attenuated state the power output from the electric flame-off controller is not reduced.

A fourth control output “D4” is connected to a roller engage mechanism 1068 of the wire feeding mechanism 106. The fourth control output “D4” toggles the roller engage mechanism 1068 between an “engaged” state where the wire feed roller 114 presses the micro-coaxial wire 102 against the wire feed block 958 and a “disengaged” state where the wire feed roller 114 is not in contact with the micro-coaxial wire 102 (e.g., for wire loading).

Finally, a pulse width modulation (PWM) output of the controller 1060 is connected to the wire feeding servo 115 and controls the speed of wire feed roller 114 and therefore the speed of the micro-coaxial wire 102 being fed by the wire feeding mechanism 106.

In some examples, a foot switch 1070 is connected to the computer 1062 and is operated by a user to control the wire bonding tool 100 in either a manual or a semi-automatic mode.

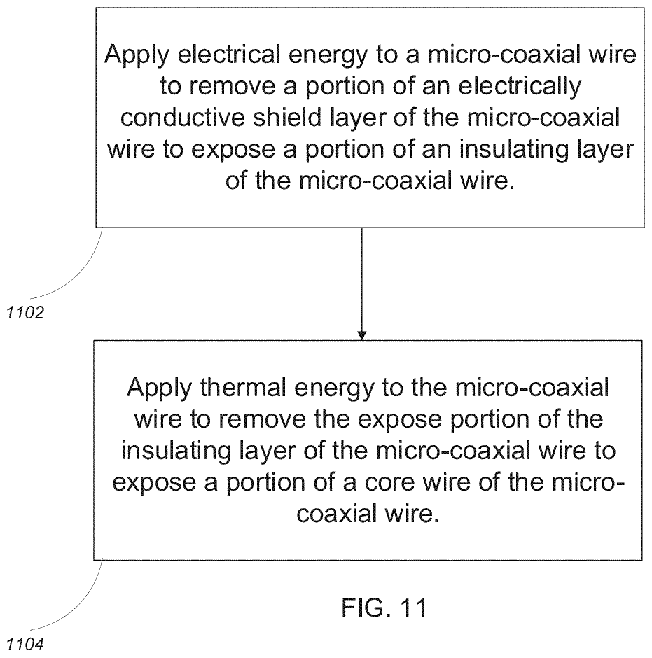

Referring to FIG. 11, a method for preparing a micro-coaxial wire for binding to a bonding surface includes two steps. In a first step 1102, electrical-energy (e.g., a spark) is applied to a micro-coaxial wire to remove a portion of an electrically conductive shield layer of the micro-coaxial wire, exposing a portion of an insulating layer of the micro-coaxial wire. In a second step 1104, thermal-energy is applied to the micro-coaxial wire to remove the exposed portion of the insulating layer of the micro-coaxial wire, exposing a portion of a core wire of the micro-coaxial wire.

### 3 Alternatives

In some examples, the wire stripping mechanism described herein is positioned above the wire feeding mechanism. But it should be recognized that the wire stripping mechanism can be positioned either above or below the wire feeding mechanism.

In some examples, the electric flame-off procedure is carried out before the thermal stripping procedure. In other examples the two procedures are carried out simultaneously.

In some examples, the electric flame-off actuator is positioned adjacent to the thermal heating element so that the system controller does not have to track two different stripping locations (electric flame-off and thermal). In other examples, the electric flame-off actuator is vertically offset from the heating element.

In some examples, micro-coaxial cables for power distribution are stripped using only an electric flame-off procedure. For example, a micro-coaxial cable with a thin dielectric (<5 μm) may be fully removed by electric flame-off procedure.

In some examples, for low impedance micro-coaxial wire (e.g., low impedance (<10 ohms) for power distribution: Cu core≤25 um, 1-5 um polymer dielectric, 2-10 um Au shield (could also be Cu)), the electric-flame-off spark may be sufficient to remove both the shield and the dielectric, exposing the core. But for higher impedance micro-coaxial wire (higher impedance for signal distribution (30-75 ohms): Cu core≤25 um, 10-40 um thermoplastic polymer, 1.5-4 um Au shield (could also be Cu)), the electric-flame-off spark will only remove the shield, and the thermal stripping apparatus is required to remove the dielectric.

One type of dielectric described herein is a Parylene dielectric. Other types of dielectrics can also be used such as polyurethane and polyethylene dielectrics. Such alternative dielectrics have lower decomposition temperatures, therefore lower electric flame-off power settings can be used, reducing the risk of cleaving the core conductor wire.

In some examples, residual polymer can be cleaned from the conductive core wire using O₂ plasma.

In some examples, a blade is used to control the shield peel-back distance caused by the electric flame-off actuator by creating a mechanical etch stop on the shield. In other examples, the power and time settings of the electric flame-off actuator are used to control the shield peel-back distance.

In some examples, an additional port is added to remove debris from the micro-coaxial wire as it is being stripped. This could be vacuum, gas or other fluid flow. If oxygen gas is used during EFO, the spark may create an ozone plasma that would clean the core of the wire by removing organic debris.

In some examples, the wire feeding and stripping mechanisms described above are implemented as a stand-alone device. In other examples, the wire feeding and stripping mechanisms described above are retrofitted onto a preexisting wire bonding machine such as a K&S automated wire bonder or a Westbond universal ultrasonic bonding machine.

Furthermore, the approaches described above can be combined with or used to improve or modify the approaches described in the following pending patent applications, each of which is incorporated herein by reference:
U.S. Ser. No. 62/545,561, filed Aug. 15, 2017, titled “Electric-Flame-Off Stripped Micro Coaxial Wire Ends,” and
U.S. Ser. No. 62/590,806, filed Nov. 27, 2017, titled “Micro-Coaxial Wire Bonding.”

It is to be understood that the foregoing description is intended to illustrate and not to limit the scope of the invention, which is defined by the scope of the appended claims. Other embodiments are within the scope of the following claims.

What is claimed is:

1. A wire bonding tool for bonding a micro-coaxial wire to a bonding surface, the wire bonding tool comprising:
an electrical-energy application mechanism configured to apply electrical-energy to remove a portion of an electrically conductive shield layer of the micro-coaxial wire to expose a portion of an insulating layer of the micro-coaxial wire;
a thermal-energy application mechanism configured to apply thermal-energy to the micro-coaxial wire to remove the exposed portion of the insulating layer of the micro-coaxial wire to expose a portion of a core wire of the micro-coaxial wire; and
a bonding head configured to bond the exposed portion of the core wire of the micro-coaxial wire to the bonding surface.

2. The wire bonding tool of claim 1 wherein the bonding head is further configured to bond a portion of the shield layer proximal to the exposed portion of the core wire to a second bonding surface.

3. The wire bonding tool of claim 1 further comprising a positioning mechanism located proximal to the bonding head and configured to position the exposed portion of the core wire for bonding to the bonding surface.

4. The wire bonding tool of claim 1 wherein the electrical-energy application mechanism is disposed at a first distance from the bonding head along a path of travel of the micro-coaxial wire and the thermal-energy application mechanism is disposed at a second distance from the bonding head along the path of travel of the micro-coaxial wire.

5. The wire bonding tool of claim 4 wherein the first distance and the second distance are equal.

6. The wire bonding tool of claim 1 wherein the thermal-energy application mechanism includes one or more resistively heated elements.

7. The wire bonding tool of claim 6 wherein the thermal-energy application mechanism includes one or more guide elements for maintaining the micro-coaxial wire in a position on or near the one or more resistively heated elements.

8. The wire bonding tool of claim 7 wherein the one or more guide elements includes a plurality of ceramic members positioned adjacent to the one or more resistively heated elements.

9. The wire bonding tool of claim 6 wherein the one or more resistively heated elements includes a first resistively heated wire configured to have a first current flow in a first direction therethrough and a second resistively heated wire configured to have a second current flow in a second direction, opposite to the first direction, therethrough, whereby a magnetic field is induced causing the first resistively heated wire and the second resistively heated wire to approach each other.

10. The wire bonding tool of claim 1 wherein the electrical-energy application mechanism is configured to apply an electric spark to the shield layer of the micro-coaxial wire.

11. The wire bonding tool of claim 10 wherein the electric spark includes a high-voltage plasma discharge.

12. The wire bonding tool of claim 1 further comprising a debris removal mechanism for removal of debris from one or both of the exposed portion of the insulating layer of the micro-coaxial wire and the exposed portion of the core wire of the micro-coaxial wire.

13. The wire bonding tool of claim 1 further comprising a feed mechanism for feeding the micro-coaxial wire through the wire bonding tool along a wire travel axis.

14. The wire bonding tool of claim 13 wherein the feed mechanism includes a servo motor configured to rotate a wire feed roller engaged with the micro-coaxial wire.

15. The wire bonding tool of claim 14 wherein the wire feed mechanism is rotatable about a hinge into a first position where the wire feed roller is engaged with the micro-coaxial wire and into a second position where the wire feed roller is disengaged from the micro-coaxial wire.

16. The wire bonding tool of claim 15 wherein the wire feed mechanism is biased toward the first position by a spring.

17. The wire bonding tool of claim 1 wherein the thermal-energy application mechanism includes a manifold for directing a forced gas onto the micro-coaxial wire.

18. The wire bonding tool of claim 17 wherein the forced gas includes nitrogen gas.

19. The wire bonding tool of claim 17 wherein the forced gas includes a cooling gas.

20. The wire bonding tool of claim 1 wherein one or both of the thermal-energy application mechanism and the electrical-energy application mechanism includes adjustment elements for adjusting a position of portions of the mechanisms and the micro-coaxial wire.

21. A method for preparing a micro-coaxial wire for bonding to a bonding surface, the method comprising:
applying electrical-energy to a micro-coaxial wire to remove a portion of an electrically conductive shield layer of the micro-coaxial wire to expose a portion of an insulating layer of the micro-coaxial wire; and
applying thermal-energy to the micro-coaxial wire to remove the exposed portion of the insulating layer of the micro-coaxial wire to expose a portion of a core wire of the micro-coaxial wire.

22. The method of claim 17 wherein the electrical-energy and the thermal energy are applied simultaneously.
